(19) United States
(12) Patent Application Publication
(10) Pub. No.: US 2010/0157514 A1
(43) Pub. Date: Jun. 24, 2010

(54) DISPLAY APPARATUS AND DISPLAY MODULE INCLUDING THE SAME

(75) Inventor: Michiko Johnson, Machida-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/636,981

(22) Filed: Dec. 14, 2009

(30) Foreign Application Priority Data
Dec. 19, 2008 (JP) 2008-324462

(51) Int. Cl. H05K 5/00

(52) U.S. Cl. 361/679.01

(57) ABSTRACT

A display apparatus includes a substrate including an effective display region and a non-effective display region, and a sealing member covering at least the effective display region. A colored member is provided from a region on the sealing member over the non-effective display region to a region on the substrate outside the sealing member.

### BACKGROUND OF THE INVENTION

1. Field of the Invention

The present invention relates to a display apparatus and a display module.

2. Description of the Related Art

In recent years, various digital devices have been equipped with a thin display. Particularly in devices that are used outside such as mobile devices, the display is required to be easily viewable under external light. Thin displays are characterized in that regions that readily reflect external light, such as wiring and a sealing region, are formed around the display region. Reflection from such regions deteriorates outdoor viewability.

To reduce the influence of such external light reflection, Japanese Patent Laid-Open No. 2005-317271 discloses a structure that prevents external light from being incident on wiring and the like outside the effective display region.

In particular, Japanese Patent Laid-Open No. 2005-317271 discloses a configuration in which a colored layer prevents reflection at wiring and the like outside the effective display region. Japanese Patent Laid-Open No. 2004-348971 discloses a configuration in which a colored layer is provided in the non-luminescent region of the sealing substrate.

Although the configuration disclosed in Japanese Patent Laid-Open No. 2005-317271 can prevent reflection of external light at wiring and the like outside the effective display region, it cannot prevent surface reflection at the sealing region (the region bonding the sealing glass plate) and the part of the sealing glass plate itself outside the effective region.

In the configuration disclosed in Japanese Patent Laid-Open No. 2004-348971, adhesive for bonding the sealing glass plate and the substrate is not colored, and therefore light can escape through the adhesive. If light escapes through the adhesive at the edge surface of the sealing member to the outside of the display apparatus or the outside of the display module, the light can be noise for a light detecting sensor provided inside, such as a camera.

### SUMMARY OF THE INVENTION

The present invention provides a display apparatus or a display module that can further reduce the influence of external light reflection outside the effective display region and can prevent light from escaping the display apparatus or the display module.

In an aspect of the present invention, a display apparatus includes a substrate including an effective display region where a display element is formed and a non-effective display region where no display element is formed, and a sealing member covering the effective display region and the non-effective display region. A colored member is continuously provided from a region on the sealing member over the non-effective display region to a region on the substrate outside the sealing member.

Further features of the present invention will become apparent from the following description of exemplary embodiments with reference to the attached drawings.

### BRIEF DESCRIPTION OF THE DRAWINGS

FIG. 1 is a side view showing a first embodiment of a display module of the present invention.

FIG. 2 is a side view showing a second embodiment of a display module of the present invention.

FIG. 3 is a side view showing a third embodiment of a display module of the present invention.

FIG. 4 is a side view showing a fourth embodiment of a display module of the present invention.

### DESCRIPTION OF THE EMBODIMENTS

The embodiments of the present invention will now be described with reference to the drawings.

### First Embodiment

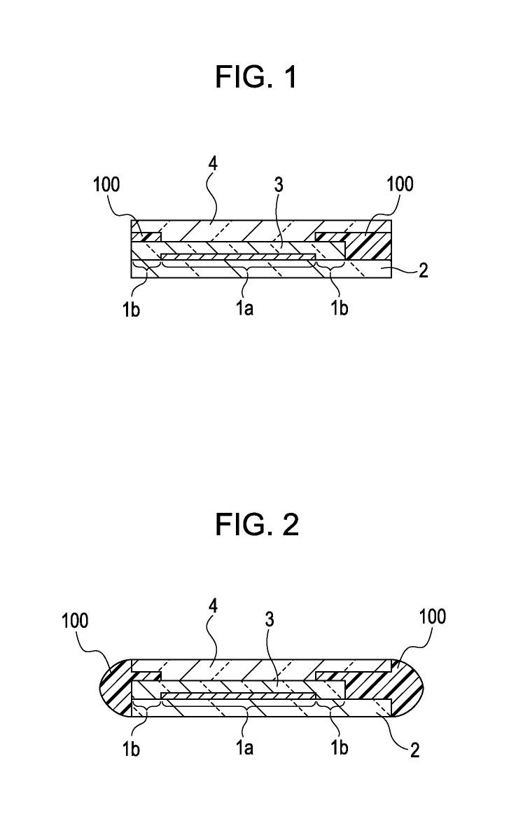

FIG. 1 is a side view showing a first embodiment of a display apparatus of the present invention. Reference numeral 1a denotes an effective display region where at least one display element is formed. A liquid crystal element, an organic EL element, or the like can be used as a display element. Reference numeral 1b denotes a non-effective display region. In this non-effective display region, no display element is formed, and part of the circuit of the substrate, a wiring region, a sealing region that seals the gap between the sealing member and the drive substrate, and the like are disposed.

Reference numeral 2 denotes a substrate. On the surface of the substrate 2, a drive circuit, a peripheral circuit, wiring connecting them, a planarizing film that planarizes them, and the like are formed. The above-described display element is formed on this substrate 2. Reference numeral 3 denotes a sealing member bonded to the substrate 2. The sealing member 3 can be selected from a glass plate (single plate glass), a glass plate having a recess corresponding to the effective display region, a resin film (organic film), an inorganic film, a multilayer film including resin and inorganic films, a resin plate, or the like. Reference numeral 100 denotes a colored member. The colored member 100 can be formed by various methods such as printing, application, and bonding sheets together. The colored member is formed of a material that is black or opaque to observation light.

Reference numeral 4 denotes a protective cover for protecting the surface of the sealing member 3 placed on the effective display region. The protective cover 4 is formed of a transparent material such as acrylic resin (PMMA (polymethyl methacrylate)), polycarbonate (PC), or glass.

A method for forming the colored member 100 of this embodiment will be described in detail.

The boundary between the effective display region 1a where a display element is formed and the non-effective display region 1b where no display element is formed can be specified visually or using an alignment mark as viewed from the front of the display apparatus. Using this boundary, the colored member 100 is formed only in a region on the sealing member 3 corresponding to the non-effective display region 1b.

It is desirable that the colored member 100 have such a thickness that the colored member 100 is opaque to observation light.

Screen printing is suitable for forming the colored member 100. In the case where a plurality of display apparatuses are made by cutting a large substrate, colored members can be formed at a time on the plurality of display apparatuses before cutting by screen printing.

Alternatively, the colored member 100 may be formed by application using a dispenser. In the case where a colored member is formed above a large display element, this method reduces waste of coloring material and enables low-cost production. Alternatively, the colored member 100 may be formed by bonding sheets together.

The method for fixing a colored member after forming the colored member can be selected from thermal curing, curing by mixing two liquids, drying, UV curing, or combination of UV curing and thermal curing according to the material of the colored member. In the case of fixing by heating, the fixing process can double as an annealing process, aging process, or the like that is separately needed, to reduce the number of processes for manufacturing a display apparatus.

Next, the assembly procedure of the display module of the first embodiment will be described.

The substrate 2 may be a large substrate before cutting or a cut substrate. The substrate 2 has an effective display region 1a and a non-effective display region 1b, and the boundary therebetween can be specified visually or using an alignment mark as viewed from the front of the display apparatus.

In the configuration of FIG. 1, the protective cover 4 has a protruding portion corresponding to the effective display region 1a of the substrate 2. First, the protective cover 4 is placed in such a manner that the distance between the outer edge of the protruding portion of the protective cover 4 and the outer edge of the effective display region 1a is uniform in the vertical and horizontal directions.

Next, the protective cover and the panel are fixed so as not to move relative to each other. After that, at least the gap between the protective cover 4 and the sealing member 3 is filled with a colored member 100 (a colored adhesive resin is used in this embodiment), and the protective cover 4 and the sealing member 3 are bonded.

At this time, the space between the protective cover 4 and the substrate 2 may also be filled with the colored member 100.

At this time, the colored member 100 is continuously provided from a region on the sealing member 3 over the non-effective display region to a region on the substrate 2 outside the sealing member 3.

Thus, a display module can be obtained in which light is prevented from escaping the non-effective display region 1b by a colored member 100 not only in the light taking out direction but also in the side surface direction.

The configuration of this embodiment prevents reflection at the wiring in the non-effective display region, reflection at the sealing region of the sealing member, and reflection at the surface of the sealing member. In addition, the configuration of this embodiment eliminates the need for the process for bonding the protective cover, thereby improving productivity. Thus, the process for securing with screws or by mechanical assembly can be eliminated.

### Second Embodiment

FIG. 2 is a side view showing a second embodiment of a display module of the present invention.

The same reference numerals will be used to designate the same components as those in the first embodiment, so the detailed description thereof will be omitted. This embodiment differs from the first embodiment in that the colored member 100 is formed so as to continuously cover the side surface of the substrate 2 and the side surface of the protective cover 4.

The configuration of this embodiment prevents reflection at the wiring in the non-effective display region, reflection at the sealing region of the sealing member, and reflection at the surface of the sealing member. In addition, the configuration of this embodiment prevents light from escaping the display module through the side surface of the protective cover and the side surface of the substrate.

Such a configuration is effective for a device that disfavors light leakage, such as a camera.

### Third Embodiment

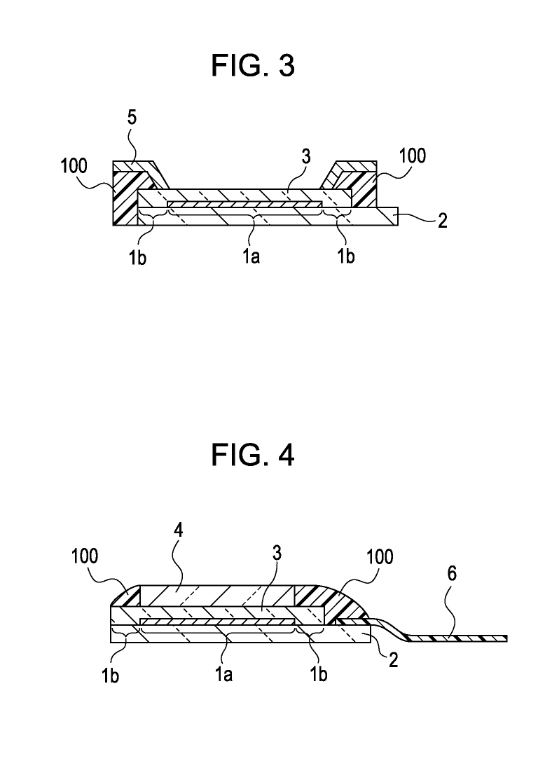

FIG. 3 is a side view showing a third embodiment of a display module of the present invention. The same reference numerals will be used to designate the same components as those in the above embodiments, so the detailed description thereof will be omitted.

Reference numeral 5 denotes a cover (case) placed over the non-effective display region 1b. The case 5 is formed of metal, plastic, or the like and may double as the exterior of a product equipped with the display module. The case 5 has an opening that is slightly larger than the effective display region 1a. The effective display region 1a is disposed in the opening as viewed from the front.

The assembly procedure of the display module of the third embodiment will be described.

The substrate 2 may be a large substrate before cutting or a cut substrate. The substrate 2 has an effective display region 1a and a non-effective display region 1b, and the boundary therebetween can be specified visually or using an alignment mark as viewed from the front of the display apparatus.

First, the case 5 is placed in such a manner that the distance between the inner edge of the case 5 and the outer edge of the effective display region 1a is uniform in the vertical and horizontal directions. Next, the case 5 and the substrate 2 are fixed, for example, mechanically, and after that, at least the space between the case 5 and the sealing member 3 is filled with a colored member 100 (a colored adhesive resin is used in this embodiment), and the case 5 and the sealing member 3 are bonded.

At this time, the colored member 100 is continuously provided from a region on the sealing member 3 over the non-effective display region to a region on the substrate 2 outside the sealing member 3. Thus, a display module can be obtained in which light is prevented from escaping the non-effective display region 1b by a colored member 100 not only in the light taking out direction but also in the side surface direction. The side surface of the substrate 2 may also be covered with the colored member 100.

The configuration of this embodiment prevents reflection at the wiring in the non-effective display region, reflection at the sealing region of the sealing member, and reflection at the surface of the sealing member.

In addition, the configuration of this embodiment eliminates the need for the process for fixing the case to the display apparatus, thereby improving productivity. Thus, the process for securing with screws or by mechanical assembly can be eliminated.

### Fourth Embodiment

FIG. 4 is a side view showing a fourth embodiment of a display module of the present invention. The same reference numerals will be used to designate the same components as those in the above embodiments, so the detailed description thereof will be omitted. Reference numeral 6 denotes a flexible substrate mounted on the substrate 2.

The assembly procedure of the display module of the fourth embodiment will be described.

The substrate 2 may be a large substrate before cutting or a cut substrate. The substrate 2 has an effective display region 1a and a non-effective display region 1b, and the boundary therebetween can be specified visually or using an alignment mark as viewed from the front of the display apparatus.

First, the protective cover 4 is placed in such a manner that the distance between the outer edge of the protective cover 4 and the outer edge of the effective display region 1a is uniform in the vertical and horizontal directions. Next, the protective cover 4 and the substrate 2 are fixed, for example, mechanically, and after that, the non-effective display region and the flexible substrate mounting region are covered with the colored member 100 (a colored adhesive resin is used in this embodiment), and the protective cover 4 and the substrate 2 are bonded.

At this time, the colored member 100 is continuously provided from a region on the sealing member 3 over the non-effective display region to a region on the substrate 2 outside the sealing member 3. Thus, a display module can be obtained in which light is prevented from escaping the non-effective display region 1b by a colored member 100 not only in the light taking out direction but also in the side surface direction.

Thus, a display module can be obtained in which light is prevented from escaping the non-effective display region of the substrate 2 by a colored member 100 not only in the light taking out direction but also in the side surface direction and a mounted component is protected.

Mounted components are not limited to a flexible substrate but include an IC chip and other semiconductor devices.

The configuration of this embodiment prevents reflection at the wiring in the non-effective display region, reflection at the sealing region of the sealing member, and reflection at the surface of the sealing member. In addition, the configuration of this embodiment protects a component mounted on the display module. Thus, the process for covering a component with silicone resin or UV resin after mounting the component can be eliminated to improve productivity.

While the present invention has been described with reference to exemplary embodiments, it is to be understood that the invention is not limited to the disclosed exemplary embodiments. The scope of the following claims is to be accorded the broadest interpretation so as to encompass all modifications and equivalent structures and functions.

This application claims the benefit of Japanese Patent Application No. 2008-324462 filed Dec. 19, 2008, which is hereby incorporated by reference herein in its entirety.

What is claimed is:

1. A display apparatus comprising:
a substrate including an effective display region where a display element is formed and a non-effective display region where no display element is formed; and
a sealing member covering the effective display region and the non-effective display region,
wherein a colored member is continuously provided from a region on the sealing member over the non-effective display region to a region on the substrate outside the sealing member.

2. The display apparatus according to claim 1, wherein the side surface of the substrate is covered by the colored member.

3. The display apparatus according to claim 1, wherein wiring is provided on the substrate, and the wiring is covered by the colored member.

4. The display apparatus according to claim 1, wherein the colored member is black or opaque to observation light.

5. A display module comprising:
a substrate including an effective display region where a display element is formed and a non-effective display region where no display element is formed;
a sealing member covering the effective display region and the non-effective display region; and
a cover disposed on at least part of the sealing member,
wherein a colored member is continuously provided from a region on the sealing member over the non-effective display region to a region on the substrate outside the sealing member.

6. The display module according to claim 5, wherein the cover is a protective cover that protects the surface of the sealing member, and the colored member is formed so as to cover the edge surface of the protective cover.

7. The display module according to claim 5, wherein the cover is a protective cover that protects the surface of the sealing member, and the colored member fills at least the space between the protective cover and the sealing member.

8. The display module according to claim 5, wherein the cover is part of a case attached to the display apparatus, and the colored member fills at least the space between the case and the sealing member.
